(19) United States
(12) Patent Application Publication
(10) Pub. No.: US 2026/0338864 A1
(43) Pub. Date: Oct. 29, 2026

(54) SMART SWITCH DEVICE FOR SWITCHING CAPACITIVE LOADS

(71) Applicant: Infineon Technologies AG, Neubiberg (DE)

(72) Inventors: Robert Illing, Finkenstein (AT); Alexander Mayer, Deisenhofen (DE)

(21) Appl. No.: 19/644,392

(22) Filed: Apr. 10, 2026

(30) Foreign Application Priority Data
Apr. 23, 2025 (DE) 102025115677.8

(51) Int. Cl. G01R 31/327; G01K 3/00; G01R 19/165; H03K 17/082

(52) U.S. Cl. CPC G01R 31/3277; G01K 3/005; G01R 19/16576; H03K 17/0822

(57) ABSTRACT

A circuit which can be used in a smart switch device is described herein. Accordingly the circuit includes an electronic switch coupled between a supply node and an output node; a logic circuit configured to output a control signal based on an input signal; a driver circuit configured to switch the electronic switch on and off in accordance with the control signal; a mode switch circuit configured signal a first mode of operation based on a mode selection signal; a monitoring circuit configured to receive a signal indicative of a voltage drop across the electronic switch and to determine, in the first mode of operation, whether the voltage drop across the electronic switch is lower than a first threshold value.

### TECHNICAL FIELD

The present disclosure relates to the field of smart electronic switches, in particular to an electronic switch for improved switching of capacitive loads.

### BACKGROUND

Various types of so-called smart semiconductor switches are known for different applications (e.g. in automotive or industrial applications). Such semiconductor switches include supplemental circuits besides the switching element (usually a high-side power MOS transistor). These supplemental circuits may be designed to switch the switching element on and off and, output diagnostic information (e.g. load current, temperature, etc.), and provide protective functions e.g. to protect the switch against overload (e.g. due to excessive temperature or excessive load currents). A smart semiconductor switch may also comprise multiple channels, each of which includes a switching element for driving a load.

Smart semiconductor switches may comprise temperature sensors, and also a protective circuit that deactivates the switch in the event of excessive temperature in order to prevent a thermal overload. In some applications, both the junction temperature of the semiconductor switch and a chip temperature measured outside the active area of the semiconductor switch (i.e. at a certain distance from the MOS channel in case of a MOSFET). The protective circuit may then evaluate e.g. the temperature difference between the junction temperature and the chip temperature measured outside the active area. A current measuring circuit may also be implemented in order to measure the load current flowing through the semiconductor switch. In the simplest case, a current measuring resistor can be used for current measurement. However, other approaches for current measurement are also known, such as e.g. the use of a few transistor cells as a “sense transistor”. The thresholds for an overcurrent shutdown or an overtemperature shutdown can be configurable, with the result that the smart semiconductor switch can be adapted to different applications.

For some applications, such as for example switching capacitive loads, existing concepts are inflexible, and there is room for improvements.

### SUMMARY

A circuit which can be used in a smart switch device is described herein. Accordingly the circuit includes an electronic switch coupled between a supply node and an output node; a logic circuit configured to output a control signal based on an input signal; a driver circuit configured to switch the electronic switch on and off in accordance with the control signal; a mode switch circuit configured signal a first mode of operation based on a mode selection signal; a monitoring circuit configured to receive a signal indicative of a voltage drop across the electronic switch and to determine, in the first mode of operation, whether the voltage drop across the electronic switch is lower than a first threshold value.

Furthermore, a method for a smart switch device is described herein. In one embodiment, the method includes generating-based on an input signal-a control signal for switching an electronic switch, which is coupled between a supply node and an output node of an integrated circuit, on and off, transitioning into a first mode of operation in response to a mode selection signal; determining—in the first mode of operation—whether a voltage drop across the electronic switch is lower than a first threshold value.

### BRIEF DESCRIPTION OF THE DRAWINGS

The invention can be better understood with reference to the following drawings and descriptions. The components in the figures are not necessarily to scale; instead emphasis is placed upon illustrating the principles of the invention. Moreover, in the figures, like reference numerals designate corresponding parts. In the drawings:

FIG. 1 illustrates an example of a circuit that can be used as a smart semiconductor switch.

FIG. 2 uses exemplary timing charts to illustrate the operation of the circuit from FIG. 1 on a capacitive load.

FIG. 3 illustrates an embodiment of an improved smart switch device that includes a monitoring circuit for checking whether a capacitive load is properly charged.

FIG. 4 includes timing diagrams for illustrating the operation of the circuit of FIG. 3.

FIG. 5 illustrates a further embodiment which additionally includes a diagnosis circuit for outputting diagnosis information.

FIGS. 6 and 7 include timing diagrams for illustrating the operation of the circuits of FIGS. 3 and 5 in more detail.

FIG. 8 illustrates a modification of the circuit of FIG. 5.

FIG. 9 is a flow chart illustrated one example of a method performed by the smart switches described herein.

### DETAILED DESCRIPTION

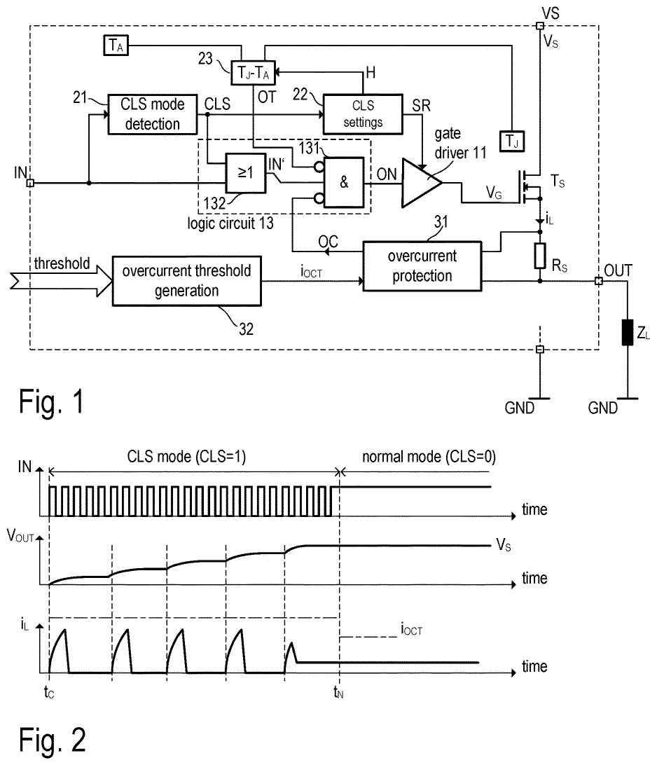

Before various exemplary embodiments are discussed in more detail, an example of a smart semiconductor switch will be explained which has a special mode of operation for switching capacitive loads. The example depicted in FIG. 1 illustrates a smart semiconductor switch having one channel, i.e. one power transistor T_{S} for driving a load. It is understood that the concepts described herein can readily be applied to multichannel systems. The switching element in the example shown is a MOS transistor, in particular a MOSFET (metal-oxide semiconductor field effect transistor) in the form of a DMOS field effect transistor (double-diffused metal-oxide semiconductor field effect transistor). It is understood that other types of switching elements may also be used, such as e.g. bipolar transistors, IGBTs (insulated gate bipolar transistors) or the like.

In the example depicted in FIG. 1, the switching element (power transistor T_{S}) is connected between an output node OUT and a supply node VS. Both, the output node OUT and the supply node VS, may be connected directly (e.g. by way of bonding wires or the like) to chip contacts (e.g. pins, solder balls, etc.). When the power transistor T_{S} is activated (i.e. switched on) the load current in flows from the supply node VS (which is connected to a power supply) via the load current path of the power transistor Ts to the output node OUT, which, during operation, is connected to a load that is symbolized by the impedance Z_{L} in the depicted example. In the present example, the power transistor T_{S} is used as a high-side switch. It is understood that the concepts described herein can readily be applied to systems using low-side switches.

The power transistor T_{S} being connected between the nodes VS and OUT does not exclude the possibility that a further element such as e.g. the current measuring resistor R_{S} may be arranged between the power transistor T_{S} and one of the nodes VS or OUT. In the depicted example, the measuring resistor R_{S} is connected between the source electrode of the (n-channel) power transistor T_{S} and the output node OUT. The voltage drop i_{L}·R_{S} across the measuring resistor Rs represents the load current i_{L} passing through the load current path of the transistor T_{S} (in the case of a MOS transistor the drain-source current path).

The control electrode of the power transistor T_{S} (i.e. the gate electrode in the case of a MOS transistor) is driven by a gate driver circuit 11. This circuit is configured to receive a logic signal ON (input signal of the gate driver), according to which the power transistor T_{S} is to be switched on and off, and the gate driver circuit 11 outputs a corresponding gate voltage V_{G} (or gate current). The gate driver 11 may also be configured to control the gradient of the switching edges (i.e. the slew rate). In the present example, the slew rate depends on the signal SR supplied to the gate driver 11. Suitable gate driver circuits are known per se and are therefore not discussed in more detail herein.

The logic signal ON is the result of a logical conjunction (implemented by logic circuit 13) of several other logic signals and/or states. In the depicted example, the logic signal ON is output by the AND gate 131, which performs the function ON=O̅T̅·IN′·O̅C̅. The dot (“·”) denotes a logic AND function and the overline above OT and OC denotes a negation. OT is a logic signal that indicates an overtemperature state, and OC is a logic signal that indicates an overcurrent state. In the example shown, both, an overtemperature state (OT=1, O̅T̅=0) and an overcurrent state (OC=1, O̅C̅=0), result in the power transistor T_{S} being switched off (because ON=0). The logic signal IN′ can be regarded as a switching command for switching the transistor T_{S} on and off. In the depicted example, it depends on an input signal received at the input node IN. The logic signal IN′ indicates that the transistor T_{S} is to be switched on, when either the input signal received at the input node IN indicates a logical “1” or the signal CLS indicates a logical “1”. CLS may also be understood as the abbreviation for “capacitive load switching”. In the present example, this OR function is performed by the OR gate 132 which outputs the logic signal IN′. The CLS mode will be explained in more detail later. Overcurrent and overtemperature protection are discussed first.

The overcurrent protection circuit 31 depicted in FIG. 1 is configured to compare the current measurement signal R_{S}·i_{L} with an overcurrent threshold value. In the present example, the overcurrent protection circuit 31 signals an overcurrent state (OC=1) if the load current in exceeds the threshold i_{OCT} (e.g. i_{L}·R_{S}>i_{OCT}·R_{S}). In essence, the overcurrent protection circuit 31 contains a comparator circuit. Suitable comparator circuits are as such known and are therefore not discussed in more detail herein. The specific implementation of the overcurrent protection circuit 31 is also dependent, inter alia, on the current measuring circuit used. Instead of the current measuring resistor R_{S} used in the example of FIG. 1, a so-called sense transistor (sense-FET) arrangement may also be used, in which some transistor cells of the power transistor are used for current measurement. Various suitable current measuring circuits are as such known and thus not further discussed in more detail herein.

The overcurrent threshold value i_{OCT} may be configurable and, in the depicted example shown, is generated by the circuit 32 (labelled “overcurrent threshold generation” in FIG. 1) based on input from an external circuit. The overcurrent protection circuit 31 receives the threshold value i_{OCT} from the circuit 32. The latter can receive a signal containing information about the desired threshold i_{OCT} from an external circuit, e.g. an external controller (not shown in the figures). In one example, the circuit 32 can communicate with an external controller by way of a digital communication interface, for example by means of an SPI (Serial Peripheral Interface). Alternatively, configuration of the threshold by means of a passive circuit component (e.g. resistor) connected to a specific chip contact (configuration pin) is also possible.

In the depicted example, two temperature values are measured. A first temperature value T_{J} represents the temperature of the transistor cell array of the power transistor T_{S} , ideally the junction temperature of the power transistor. Alternatively, a temperature measurement in the hot area close to the transistor's active area is also possible. A second temperature value T_{A} represents the chip temperature remote from the power transistor's active area, i.e. at a comparatively “cool” place on the semiconductor chip as far away as possible from the “hot spot” in the transistor cell array. Suitable temperature sensors integrated in the chip are as such known and are therefore not described in more detail herein. The overtemperature protection circuit 23 is configured indicate an overtemperature state (OT=1) based on the two measured temperature values T_{J} and T_{A}.

An overtemperature state can be triggered by various circumstances. According to one example, the overtemperature protection circuit 23 may signal an overtemperature state when the junction temperature T_{J} of the transistor T_{S} exceeds a temperature threshold (T_{J}>T_{J,max}) which, in some embodiments, may represent a permissible maximum value T_{J,max}. Furthermore, the overtemperature protection circuit 23 may signal an overtemperature state when the temperature difference T_{J}−T_{A} exceeds a temperature difference threshold value (T_{J}−T_{A}>ΔTₘₐₓ) which, in some embodiments, may represent a permissible maximum difference value ΔTₘₐₓ. The overtemperature protection circuit 23 (i.e. the comparator contained therein) can exhibit a hysteresis.

Accordingly, an overtemperature state may be signalled when the condition T_{J}−T_{A}>ΔTₘₐₓ is satisfied, but the overtemperature state may be cancelled not before the condition T_{J}−T_{A}<ΔTₘₐₓ−T_{H} is satisfied. The value T_{H} here represents the width of the hysteresis. In particular, the values ΔTₘₐₓ and T_{H} may be configurable. The value T_{J,max} may also be configurable (for example by means of a digital communication interface). The threshold values ΔTₘₐₓ and ΔTₘₐₓ−T_{H} may also depend on whether the smart semiconductor switch operates in a CLS mode, which is described below. That is, different threshold values and/or hysteresis values may be used during operation in normal mode and in CLS mode.

As mentioned, CLS refers to the switching-on of a capacitive load. Depending on the implementation, the CLS mode can be activated in different ways. By way of example, a specific chip pin may be provided, and the CLS mode can be activated if e.g. a high level is applied to this chip pin. In the depicted example, the circuit 21 (labelled “CLS mode detection” in FIG. 1) detects and activates the CLS mode if a pulse-width-modulated (PWM) signal having e.g. a duty cycle of 50 percent and a defined frequency is applied to the input node IN. Accordingly, the circuit 21 is named “mode switch circuit”. The frequency of the PWM signal can be e.g. in the kilohertz range (e.g. 30 kHz). The circuit 21 can detect this frequency in the input signal and use a high level of the logic signal CLS to indicate the CLS mode (CLS=1). A low level of the logic signal CLS signals a normal mode (CLS=0), in which the transistor T_{S} is switched on when the signal applied to the input node has a high level (without modulation).

Like in normal mode, the transistor Ts is activated/switched on in the CLS mode, but the transition to the CLS mode results in some operating parameters of the smart semiconductor switch being altered. In the example shown in FIG. 1, the circuit 22 (labelled “CLS settings” in FIG. 1) may be designed to reconfigure the gate driver 11 in such a way that the slew rate (SR) of the switching edges is lowered (as compared to the normal mode). In one embodiment, the slew rate is a factor 10 lower in CLS mode as compared with operation in normal mode. Furthermore, the circuit 22 may be designed to reconfigure the parameters (temperature threshold values and hysteresis) of the overtemperature protection circuit 23 and to reset them to the previous (standard) values again on leaving the CLS mode. For example, in CLS mode, an overtemperature state may be indicated when T_{J}−T_{A}>20K, whereas in normal mode the condition T_{J}−T_{A}>80K may apply.

The function of the smart switch device of FIG. 1 is further illustrated with reference to the timing diagrams shown in FIG. 2. The top diagram of FIG. 2 shows one example for activating the CLS mode, namely modulating the input signal supplied to the input node IN, wherein the input signal is also denoted as IN in FIG. 2. The modulation of the input signal is detected by the circuit 21, and the logic signal CLS is then set to a High level (CLS=1). Consequently, the logic signal IN′ changes to “high” (IN′=1) and so does the logic signal ON (ON=1) which results in the transistor T_{S} being switched on. FIG. 2 relates to the case of a capacitive load, resulting in a very high inrush current.

The high inrush current can result in very rapid heating of the transistor T_{S} and in a temporary overtemperature shutdown due to the condition T_{J}−T_{A}>ΔTₘₐₓ being fulfilled (OT=1 and O̅T̅=0 resulting in ON=0), wherein the value ΔTₘₐₓ may be lower in the CLS mode than in the normal mode (e.g. 20 K instead of 80 K). As a consequence of the overtemperature shutdown, the transistor Ts cools down (T_{J}−T_{A}<ΔTₘₐₓ−T_{H}), resulting in the transistor T_{S} being switched on again. The hysteresis of the overtemperature protection circuit 23 results in toggling, i.e. a regular switching off, and on again, of the transistor Ts, with the inrush current i_{L} charging the capacitance of the load further in each cycle and the output voltage V_{OUT} rising somewhat in each cycle. The gradual charging of the load capacitance is depicted in the second diagram of FIG. 2. The regular switching on and off (toggling) of the load current is depicted in the third (bottom) diagram of FIG. 2.

In the depicted example, the CLS mode ends, and normal mode begins, at time instant tv. It is understood, that the mode change from CLS mode to normal mode is actively caused by the external controller which generates the input signal IN. In the present example, the circuit 21 detects, at time instant t_{N}, that the input signal IN is at a constant High level and not modulated any more. As a consequence, the logic signal CLS is set to a low level (CLS=0) which causes a reconfiguration of the gate driver 11 and a change of the threshold values used by the overtemperature protection circuit 23. Also the threshold value i_{OCT} used by the overcurrent protection circuit 31 may be changed upon a mode transition.

As can be seen from FIG. 2, a load capacitor which is initially discharged at time instant t_{C}, when the CLS mode is activated by applying a modulated input signal IN behaves similar to a short-circuit. In fact, the smart switch of FIG. 1 is not able to distinguish a capacitive load from a short-circuit (or an overload). A short circuit will only be detected after a transition from CLS mode to normal mode, in which the short-circuit and the resulting overly high load current will trigger either an overcurrent shutdown or lead to an overtemperature shutdown.

Different from CLS mode, an overtemperature shutdown will result in a permanent switch-off when the smart switch operates in normal mode. A subsequent switch-on will have to be triggered by the external controller which generates the input signal IN, i.e. by setting the input signal IN to a Low level and subsequently triggering a switch-on by setting the input signal IN again to a High level. However, during the CLS mode, the high-currents caused by the short-circuit (overload) can heat up the semiconductor chip which may lead to an accelerated aging and degradation of the device.

In known concepts, the maximum time, which the smart switch device may safely be operated in CLS mode is specified in the product's data sheet. However, there is no protection mechanism that would protect the smart switch against being operated in CLS mode too long (i.e. longer than the specified maximum time). For example, the external controller, which outputs the modulated input signal IN may continue to output the modulated input signal at time to instead of an unmodulated input signal (e.g. due to a software error in the controller). If, in such a situation, a short-circuit occurs, the toggling of the load current i_{L} shown in FIG. 2 may continue in an endless loop because there is no capacitance that could be charged (which would bring the loop to an end). A short circuit would only be detected after a transition to normal mode, in which an overtemperature or an overcurrent shutdown is permanent, which means that the smart switch remains off until a reset is triggered by the external controller.

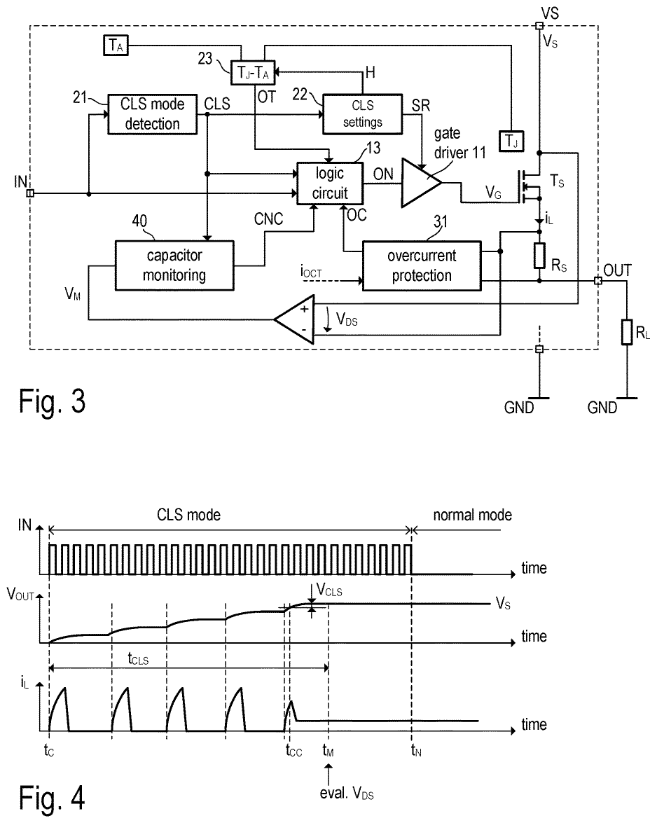

FIG. 3 illustrates a further example of a circuit that can be used as a smart semiconductor switch. The depicted circuit can be regarded as a modification/improvement of the example of FIG. 2. Like in the previous example, the an electronic switch Ts (e.g. a MOS transistor) is coupled between a supply node VS and an output node OUT of a smart switch device. The logic circuit 13 is configured to output a control signal ON based on an input signal IN and the driver circuit 11 is configured to switch the electronic switch T_{S} on and off in accordance with the control signal ON.

The mode switch circuit 21 is configured to signal a mode of operation (i.e. CLS mode/normal mode) based on a mode selection signal. In the depicted example, the input signal IN is used as mode selection signal, because a (specific) modulation of the input signal indicated the CLS mode (like in the previous example). It is understood, that in other implementations, a different signal may be used for mode selection.

Like in the previous example (FIG. 1), various parameters may be reconfigured in CLS mode such as the thresholds used for overtemperature protection, the slew rate of the gate driver 11, the overcurrent threshold i_{OCT}, etc. The overcurrent protection circuit 31, the overtemperature protection circuit 23, the gate driver and the logic circuit 13 may be substantially the same as in the previous example of FIG. 1 and reference is made to the description above to avoid unnecessary reiterations.

To prevent situations, in which the CLS mode remains active for longer than permitted in the product specification, a monitoring circuit 40 can be provided which is configured to receive a signal V_{M} indicative of a voltage drop V_{DS} across the electronic switch T_{S} and to determine (when operating in CLS mode) whether the voltage drop V_{DS} across the electronic switch T_{S} is lower than a respective threshold value V_{CLS}. In other words, the monitoring circuit 40 checks whether the condition V_{DS}<V_{CLS} is fulfilled. As mentioned, the electronic switch T_{S} can be a MOS transistor and in this case the voltage drop V_{DS} is the drain-source voltage of the transistor.

The condition V_{DS}<V_{CLS} is equivalent to the condition that the output voltage V_{OUT} is greater than V_{S}−V_{CLS} which means that the capacitance of the load Z_{L} is charged almost up to the supply voltage V_{S}. If the condition V_{OUT}>V_{S}−V_{CLS} (and thus V_{DS}<V_{CLS}) is fulfilled, then a short circuit is excluded. If the condition is not fulfilled, this is an indication for a short circuit. Accordingly, a short-circuit can be detected during the CLS mode and not only after a transition to normal mode.

The timing diagrams of FIG. 4 illustrate the function of the circuit of FIG. 3 and in particular the function of the monitoring circuit 40 in more detail. FIG. 4 illustrates a switch-on process similar to FIG. 2. The CLS mode is activated at time t_{C}, at which the capacitance of the load Z_{L} is substantially discharged, i.e. the output voltage V_{OUT}(t_{C}) is approximately zero. Therefore, a very large inrush current it will heat up the active area of the transistor T_{S} quickly which leads to the toggling of the input current i_{L} and the stepwise charging of the capacitance as described above with reference to FIG. 2. At some point (time instant t_{CC}) the output voltage V_{OUT} reaches the value V_{S}−V_{CLS}. Accordingly, the condition V_{DS}<V_{CLS} is fulfilled at and after time instant t_{CC} which indicates that the capacitance has been properly charged, which also means that there is no short circuit that would prevent the charging of the capacitor.

In the depicted example the monitoring circuit 40 is configured perform the check whether the voltage drop V_{DS} is lower than the threshold value V_{CLS} at a defined measuring time instant t_{M}, which is a delay time t_{CLS} after the mode switch circuit 21 signals activation of the CLS mode. That is, t_{M}=t_{C}+t_{CLS}. The delay time t_{CLS} is a system parameter is either fixed by circuit design or configurable (e.g. via a digital communication interface). Of course, the delay time t_{CLS} has to be long enough for the capacitance to be charged until the end of the delay time t_{CLS}. This means that the delay time t_{CLS} implicitly defines a maximum capacitance that should not be exceeded for the smart switch to function properly.

In an alternative implementation, the monitoring circuit 40 is configured to detect the time instant t_{CC} at which the voltage drop V_{DS} reaches the threshold value V_{CLS} (instead of performing the check at a defined time t_{M}). This allows the monitoring circuit 40 to signal that the output capacitance is charged as soon as the condition V_{DS}<V_{CLS} is fulfilled. The detection that the voltage drop V_{DS} has reached the threshold value V_{CLS} may be communicated to an external controller (e.g. via a digital communication interface). This enables the external controller to output a Low level input signal (IN=0) in order to deactivate (switch off) the smart switch device if the capacitor is not charged within a specific time span after activation of the smart switch.

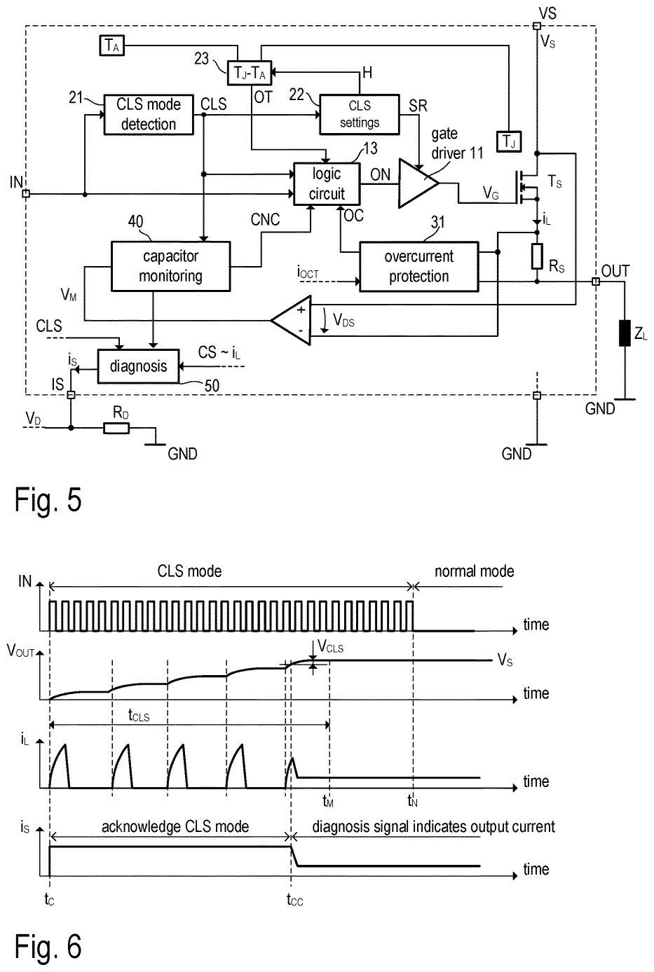

The circuit of FIG. 5 can be regarded as a modification/enhancement of the example of FIG. 3. The circuits of FIG. 5 and FIG. 3 are essentially the same except that the circuit of FIG. 5 includes an additional diagnosis circuit 50 that is configured to output various information at a dedicated chip contact IS (diagnosis pin). The diagnosis circuit may receive a current sense signal CS representing the output current i_{L}. For example, the current sense signal CS may be a voltage signal proportional to the load current, e.g. a scaled version of the voltage drop R_{S}·i_{L} across the current measuring resistor R_{S}. As mentioned, various different current measuring concepts may be applicable. The diagnosis circuit may be configured to output, during operation in normal mode, a diagnosis signal (at the diagnosis pin IS) that indicates the load current i_{L}.

In CLS mode, the diagnosis circuit 50 may output a status information instead of an output current value. In one embodiment, the diagnosis circuit 50 is configured to output a diagnosis signal indicating an error when the monitoring circuit 40 determines that the voltage drop V_{DS} across the electronic switch T_{S} is not lower than a first threshold value V_{CLS}. As mentioned, the monitoring circuit 40 may be configured to check, at a measuring time instant t_{M}, whether the condition V_{DS}<V_{CLS} is fulfilled or not. In this case, if the condition is fulfilled at time t_{M}, the diagnosis circuit 50 starts to output, at time t_{M}, a diagnosis signal that indicates the measured output current (e.g. like in normal mode). If the condition is not fulfilled at time t_{M}, the diagnosis circuit 50 starts to output, at time t_{M}, a diagnosis signal that signals and error. The error may be signaled by a specific level of the diagnosis signal (diagnosis current is). As mentioned, the measuring time instant t_{M} is a given (configurable or fixed) delay time t_{CLS} after the mode switch circuit 21 signals the CLS mode (t_{M}=t_{C}+t_{CLS}).

In another embodiment, the monitoring circuit 40 is configured to detect the time instant t_{CC} at which the voltage drop V_{DS} across the electronic switch T_{S} reaches (or crosses) the first threshold value V_{CLS}. In other words, instead of checking the condition V_{DS}<V_{CLS} at a specific time, the time instant t_{CC}, at which the condition V_{DS}<V_{CLS} is fulfilled, is detected.

In this case, the diagnosis circuit 50 may be configured to output a diagnosis signal that indicates the CLS mode. That is, the diagnosis signal acknowledges the mode switch to CLS mode as soon as the mode switch circuit 21 triggers the mode switch (e.g. at time instant t_{C} in the example of FIG. 4). As soon as the voltage V_{DS} crosses (falls below) the threshold value V_{CLS}, the diagnosis circuit 50 will output a diagnosis signal that is indicative of the output current i_{L}. However, if the voltage V_{DS} does not cross (fall below) the threshold value V_{CLS} within the delay time t_{CLS} (starting upon transition into CLS mode), the diagnosis circuit 50 will output a diagnosis signal that indicates an error.

As soon as an error is signaled as explained above, an emergency shutdown of the transistor T_{S} may be caused, e.g. by monitor circuit 40 generating a logic signal CNC that causes the logic circuit 13 to output the ON signal with a Low level. In an alternative implementation, the shutdown of the transistor T_{S} is not automatically triggered but the external controller switches off the smart switch in response to receiving the diagnosis signal indicating an error.

In some embodiments, the mode switch circuit 21 may be configured to signal normal mode of operation after signaling the CLS mode operation for a predetermined maximum time span (e.g. after the delay time t_{CLS}). In other words, the mode switch circuit 21 triggers a transition into normal mode after a predetermined maximum time of CLS mode operation, wherein the transition into normal mode is independent on whether the input signal IN or (as the case may be) a mode selection signal still indicates CLS mode operation. Accordingly, if for some reason (e.g. due to a software error) the external controller keeps generating a modulated input signal IN (which selects CLS mode), the CLS mode will nevertheless end after the predetermined maximum time (e.g. after the delay time t_{CLS}). That is, the external controller cannot keep the CLS mode active for more than the mentioned maximum time.

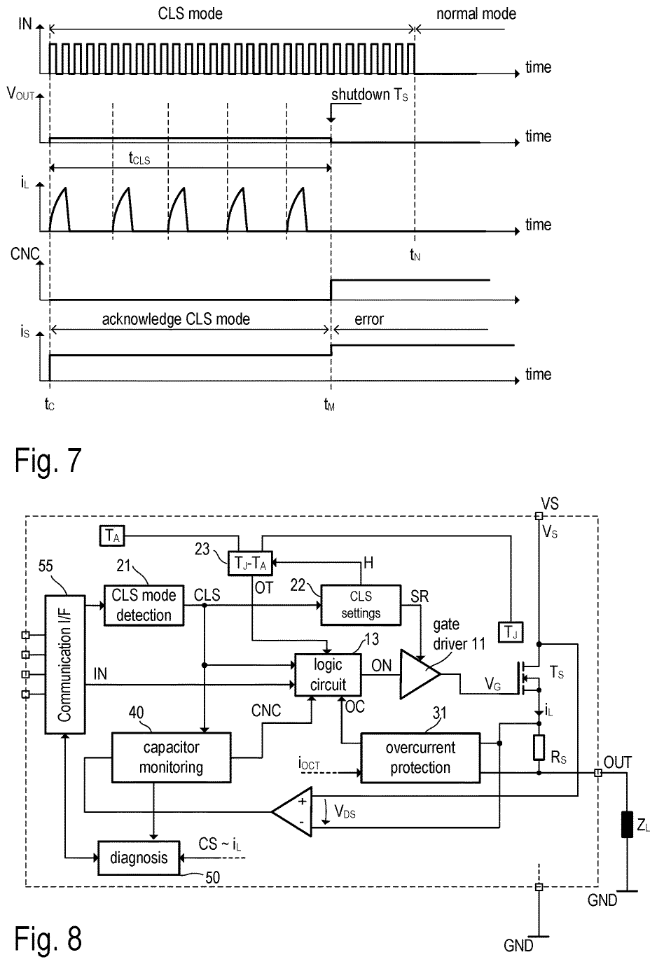

Various aspects of the embodiments described herein are summarized below. It is emphasized that the following summary is not exhaustive. First, the function of the examples discussed with reference to FIG. 5 is summarized with reference to the timing diagrams of FIGS. 6 and 7. Accordingly, a method performed by a smart switch device includes generating—based on an input signal—a control signal for switching an electronic switch, which is coupled between a supply node and an output node of an integrated circuit, on and off (see also FIG. 5, input signal IN, control signal ON, transistor T_{S}). The method further includes transitioning into a first mode of operation (CLS mode) in response to a mode selection signal. In one example, the input signal may be used as mode selection signal. In the example of FIG. 6 (top diagram), the pulse-width modulation of the input signal IN indicates the CLS mode. Due to temporary overtemperature shutdowns (which are triggered by a steep temperature rise caused by high inrush currents) the load capacitance is charged stepwise as shown in the second diagram of FIG. 6. The respective load current is shown in the third diagram of FIG. 6. The method further includes determining—in the first mode of operation (CLS mode)—whether a voltage drop across V_{DS} the electronic switch is lower than a first threshold value. As discussed above, this condition (V_{DS}<V_{CLS}) is approximately equivalent to the condition V_{OUT}>V_{DS}−V_{CLS}, wherein V_{OUT} denotes the voltage across the capacitive load Z_{L} and V_{S} denotes the supply voltage applied to the electronic switch.

In one embodiment, the method may comprise generating a diagnosis signal that signals an acknowledgement of the first mode (CLS mode) upon transition into the first mode. This acknowledgement is shown in the fourth (bottom) diagram of FIG. 6, in which the diagnosis signal is indicates the acknowledgement by a specific signal level.

In one embodiment, determining, whether the condition V_{DS}<V_{CLS} holds true, includes detecting that the voltage drop V_{DS} across the electronic switch T_{S} reaches (or falls below) the first threshold value V_{CLS}. For this purpose, the monitoring circuit 40 (see FIG. 5) may include a comparator.

In one embodiment, the method may comprise generating a diagnosis signal that signals an error when the voltage drop V_{DS} does not reach (e.g. fall below) the first threshold value V_{CLS} within a predetermined time t_{CLS} from a transition into the first mode. This error signal can be seen in FIG. 7 (fifth diagram), in which the output voltage V_{OUT} has not reached the desired value V_{S}−_{CLS} before the time t_{M}=t_{C}+t_{CLS} and, as a consequence, the diagnosis circuit 50 indicates the error by outputting the signal is with a specific level. In the depicted example, the signal level indicating the error is higher than the signal level indicating the acknowledge of the CLS mode. The fourth diagram of FIG. 7 illustrates the logic signal CNC which is set from a Low level to a High Level in response to the condition V_{DS}<V_{CLS} not being fulfilled by time t_{M}. The first three diagrams of FIG. 7 show (like in FIG. 6) the input signal IN, the output voltage V_{OUT}, and the load (output) current i_{L} is a situation in which a short circuit prevents the load capacitance from being charged. The toggling of the load current only ends at time t_{M} when the signal CNC prevents the electronic switch from being switched on again.

In one embodiment, the method includes generating a diagnosis signal that indicates a load current passing through the electronic switch as soon as the voltage drop across the electronic switch reaches or falls below the first threshold value (i.e. as soon as the condition V_{DS}<V_{CLS} is fulfilled). The output of the current measurement is shown in FIG. 6, fourth diagram. Accordingly, the diagnosis signal represents the current measurement after time instant t_{M}.

In one embodiment the method includes transitioning into a second mode of operation (e.g. normal mode) if a specific maximum time in the first mode has passed. This specific maximum time may be the same as the delay time t_{CLS} or longer.

Further embodiments relate to a circuit which can be used in a smart switch device. Accordingly the circuit includes an electronic switch coupled between a supply node and an output node; a logic circuit configured to output a control signal based on an input signal; a driver circuit configured to switch the electronic switch on and off in accordance with the control signal; a mode switch circuit configured signal a first mode of operation based on a mode selection signal; a monitoring circuit configured to receive a signal indicative of a voltage drop across the electronic switch and to determine, in the first mode of operation, whether the voltage drop across the electronic switch is lower than a first threshold value (in order to determine whether a capacitance included in a load connected to the output node is sufficiently charged). See, for example, FIG. 5 (logic circuit 13, driver circuit 11, electronic switch T_{S}, mode switch circuit 21).

In one embodiment, the circuit further includes a diagnosis circuit configured to output a diagnosis signal indicating an error when the monitoring circuit (see FIGS. 3 and 5, monitoring circuit 40) determines that the voltage drop across the electronic switch is not lower than a first threshold value (i.e. when the monitoring circuit determines that the condition V_{DS}<V_{CLS} is not fulfilled).

In one embodiment this determination (that the condition V_{DS}<V_{CLS} is not fulfilled) is made at a measuring time t_{M}. Therefore, the monitoring circuit may be configured to check, at the measuring time t_{M}, whether the voltage drop across the electronic switch is lower than the first threshold value. The measuring time instant t_{M} may be a delay time T_{CLS} after the mode switch circuit signals (the transition into) the first mode.

In one embodiment the circuit includes a diagnosis circuit (see, for example, FIG. 5, diagnosis circuit 50) configured to output a diagnosis signal indicating an error when, at the measuring time instant t_{M}, the monitoring circuit (40) determines that the voltage drop across the electronic switch is not lower than a first threshold value V_{CLS} (i.e. that the condition V_{DS}<V_{CLS} is not fulfilled). The diagnosis signal indicating an error is illustrated in FIG. 7 bottom diagram.

In one embodiment, the determination (that V_{DS}<V_{CLS}) includes the monitoring circuit detecting a time instant t_{CC}, at which the voltage drop V_{DS} across the electronic switch reaches the first threshold value. Accordingly, the determination is not made at a specific time (like t_{M} in the previous example) but the monitoring circuit detects the event of the voltage V_{DS} crossing the respective threshold V_{CLS}. The time instant at which this event occurs is denoted t_{CC} in FIGS. 4 and 6. It is noted that, in the embodiments described herein, it practically does not make any difference if the voltage VDS reaches the threshold V_{CLS} (i.e. V_{DS}≤V_{CLS}) or falls below the threshold (i.e. V_{DS}<V_{CLS}). The conditions V_{DS}≤V_{CLS} and V_{DS}<V_{CLS} are equivalent for any practical purposes (because the V_{DS}=V_{CLS} will only be true for an infinite short time interval).

In one embodiment, the diagnosis circuit may be configured to output a diagnosis signal indicating (acknowledging) the first mode until the monitoring circuit detects the time instant t_{CC} (i.e. the condition V_{DS}<V_{CLS}). Further, the diagnosis circuit may be configured to output a diagnosis signal indicating an error when the monitoring circuit does not detect the first time instant t_{CC} (i.e. does not detect the condition V_{DS}<V_{CLS}) within a delay time t_{CLS} starting when the mode switch circuit signals (transition into) the first mode. Accordingly, an error is signalled when the capacitance of the load is not sufficiently charged after operating in CLS mode for a specific time t_{CLS}.

In one embodiment, the mode switch circuit is configured to signal a second mode of operation (i.e. normal mode) after signalling the first mode of operation (i.e. CLS mode) for a predetermined maximum time span. This predetermined maximum time span may be equal to the time span t_{CLS} or longer. This feature prevents an external controller enforcing the CLS mode for a time longer than the predetermined maximum time span.

In the embodiments described herein, the circuit may comprise a overtemperature protection circuit (see FIG. 5, overtemperature protection circuit 23) coupled to the logic circuit and configured to signal an overtemperature state (e.g. by outputting OT=1) to the logic circuit, thus causing the logic circuit to switch off the electronic switch as long as the overtemperature state persists.

As explained further above, the overtemperature protection circuit may signals an overtemperature state when a temperature value (e.g. the measured temperature difference T_{J}−T_{A}) exceeds a first temperature threshold (e.g. a maximum allowed temperature difference ΔTₘₐₓ), wherein the overtemperature state persists until the temperature value falls below a second temperature threshold (e.g. the maximum allowed temperature difference minus a hysteresis offset ΔTₘₐₓ−T_{H}). This temperature dependent switch-off of the electronic switch leads to the toggling of the load current (output current i_{L}) as shown in FIGS. 4, 6 and 7.

The diagnosis circuit discussed in connection with FIG. 5 is configured to output a current signal is as diagnosis signal. This current signal can be converted to a voltage signal by connecting an external resistor R_{IS} to the diagnosis pin IS of the integrated circuit. This allows an external controller to sense the voltage drop i_{S}·R_{IS} across this resistor R_{IS}, e.g. by using an analog-to-digital converter. It is emphasized that the analog implementation of FIG. 5 is merely an example. In other embodiments, the diagnosis circuit may be coupled to a digital communication interface such as a Serial Peripheral Interface (SPI) which allows to digitally communicate with other circuits such as a microcontroller or the like. In this case the diagnosis signal is a digital signal which is sent via the communication interface, e.g. in the form of a serial bit stream (e.g. a data frame). The digital communication interface may also be used to receive digital switch-on commands. In this case, the input signal IN and the mode selection signal may be provided by the digital communication interface based on the data receive via the digital communication link.

FIG. 8 illustrates a modification of the circuit of FIG. 5. The circuits of FIG. 8 and FIG. 5 are essentially the same except that the circuit of FIG. 5 includes a digital communication interface 55, for example a serial communication interface such as an SPI which allows the digital communication with other integrated circuits, in particular with microcontrollers. In the present example, the digital communication interface 55 provides all input/output (I/O) functions of the smart switch device. In FIG. 8 the communication interface 55 is connected to four bus lines (e.g. input data, output data, serial clock, and chip select).

The digital communication interface 55 may particularly replace the diagnosis circuit 50, which outputs an analog current is at the diagnosis pin IS. Instead, the diagnosis circuit 50 may be configured to provide diagnosis information (e.g. in the form of a digital word) to the digital communication interface 55 which then can communicate the diagnosis information to an external circuit (e.g. a microcontroller). The digital communication interface 55 may also replace the input pin IN. Instead, the digital communication interface 55 may be configured to receive a switch-on command and provide a logic signal indicating switch-on, e.g. via a High level, the upon the reception of such a command. Similarly, a Low level may be output upon reception of a switch-off command.

The mentioned switch-on command may also include information (e.g. a specific bit being set) indicating that an activation of the CLS mode is desired. In this case, the mode switch circuit 21 simply needs to generate the logic signal CLS re response to the digital communication interface 55 receiving such a command. Apart from the implementation of the I/O functions, the circuit of FIG. 8 is the same as the circuit of FIG. 5 and reference is made to the respective description above.

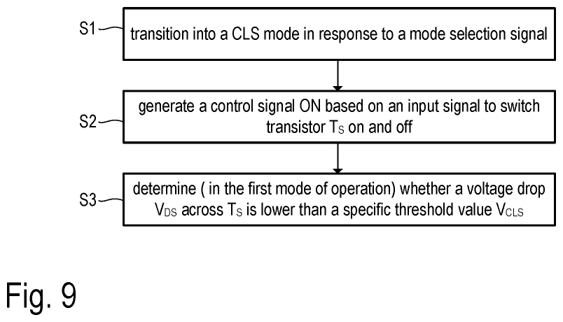

The function of the embodiments described herein are summarized below with reference to the flow chart of FIG. 9. It is noted that the steps of FIG. 9 may be reordered (in a different order). Accordingly, a method for operating a smart switch device may include the generation of a control signal, based on an input signal, for switching an electronic switch on and off (see, e.g. FIGS. 3, 5, and 8, control signal ON, electronic switch Ts, and FIG. 9, box S2). The method further includes transitioning the device into CLS mode (first mode of operation) in response to a mode selection signal (see FIG. 9, box S1) and determining—in the first mode of operation—whether a voltage drop VDs across the electronic switch is lower than specific threshold value V_{CLS} (see timing diagrams of FIG. 4 and 6-7, and FIG. 9, box S3).

In one example, the method includes the generation of a diagnosis signal that indicates an acknowledgement of the first mode (CLS mode) upon transition into the first mode (see, e.g. timing diagrams of FIG. 6-7).

In one example, the determining whether the voltage drop V_{DS} is lower than the threshold value V_{CLS} comprises: detecting that the voltage drop V_{DS} reaches the threshold value V_{CLS} (seem e.g. FIG. 6, time instant t_{CC}). A diagnosis signal indicating an error may be generated in response to the voltage drop V_{DS} not reaching the threshold value V_{CLS} within a predetermined time t_{CLS} from a transition into the first mode (see FIG. 7, time span t_{CLS} ends at time instant t_{M}). However, if (and as soon as) the voltage drop V_{DS} does reach the threshold value V_{CLS}, the diagnosis signal may indicate/represent the load current passing through the electronic switch (see FIG. 6, after time t_{CC}).

In some embodiments, the method may include transitioning the device into normal mode (second mode of operation) if a specific maximum time in CLS mode has passed. This feature prevents the device from operating in CLS mode for more than the maximum time even if no mode change is signaled from an external controller.

In some embodiments, the method may include the detection of an overtemperature state and switching off the electronic switch as long as the overtemperature state persists. The detection of the overtemperature state may include detecting that a (measured) temperature value T_{J}−T_{A} exceeds a first temperature threshold ΔTₘₐₓ, and detecting that the temperature value T_{J}−T_{A} falls below a second temperature threshold ΔTₘₐₓ−T_{H} which indicates the end of the overtemperature state (see FIGS. 3, 5 and 8, overtemperature protection circuit 23). The temperature threshold ΔTₘₐₓ and the hysteresis T_{H} may be different in the first and the second mode of operation (normal mode and CLS mode).

Although the invention has been illustrated and described with respect to one or more implementations, alterations and/or modifications may be made to the illustrated examples without departing from the spirit and scope of the appended claims. In particular regard to the various functions performed by the above described components or structures (units, assemblies, devices, circuits, systems, etc.), the terms (including a reference to a “means”) used to describe such components are intended to correspond—unless otherwise indicated—to any component or structure, which performs the specified function of the described component (e.g., that is functionally equivalent), even though not structurally equivalent to the disclosed structure, which performs the function in the herein illustrated exemplary implementations of the invention.

1. A circuit comprising:
an electronic switch coupled between a supply node and an output node
a logic circuit configured to output a control signal based on an input signal
a driver circuit configured to switch the electronic switch on and off in accordance with the control signal,
a mode switch circuit configured signal a first mode of operation based on a mode selection signal; and
a monitoring circuit configured to receive a signal indicative of a voltage drop across the electronic switch and to determine, in the first mode of operation, whether the voltage drop across the electronic switch is lower than a first threshold value

2. The circuit of claim 1, further comprising:
a diagnosis circuit configured to output a diagnosis signal indicating an error when the monitoring circuit determines that the voltage drop across the electronic switch is not lower than a first threshold value.

3. The circuit of claim 1,
wherein, for determining whether the voltage drop across the electronic switch is lower than the first threshold value the monitoring circuit is configured to check, at a measuring time instant whether the voltage drop across the electronic switch is lower than the first threshold value; and
wherein the measuring time instant is a delay time after the mode switch circuit signals the first mode.

4. The circuit of claim 3, further comprising:
a diagnosis circuit configured to output a diagnosis signal indicating an error when, at the measuring time instant the monitoring circuit determines that the voltage drop across the electronic switch is not lower than a first threshold value.

5. The circuit of claim 1,
wherein, for determining whether the voltage drop across the electronic switch is lower than the first threshold value the monitoring circuit is configured to detect a first time instant at which the voltage drop across the electronic switch reaches the first threshold value.

6. The circuit of claim 5, further comprising a diagnosis circuit configured to output:
a diagnosis signal indicating the first mode until the monitoring circuit detects the first time instant and
the diagnosis signal indicating an error when the monitoring circuit does not detect the first time instant within a delay time starting when the mode switch circuit signals the first mode.

7. The circuit of claim 1,
wherein the mode switch circuit is configured to signal a second mode of operation after signaling the first mode operation for a predetermined maximum time span.

8. The circuit of claim 1, further comprising:
an overtemperature protection circuit coupled to the logic circuit and configured to signal an overtemperature state to the logic circuit causing the logic circuit to switch off the electronic switch as long as the overtemperature state persists.

9. The circuit of claim 8,
wherein the overtemperature protection circuit is configured to signal the overtemperature state when a temperature value exceeds a first temperature threshold wherein the overtemperature state persists until the temperature value falls below a second temperature threshold.

10. A method comprising:
generating, based on an input signal a control signal for switching an electronic switch which is coupled between a supply node and an output node of an integrated circuit, on and off;
transitioning into a first mode of operation in response to a mode selection signal; and
determining, in the first mode of operation, whether a voltage drop across the electronic switch is lower than a first threshold value.

11. The method of claim 10, further comprising:
generating a diagnosis signal that signals an acknowledgement of the first mode upon transition into the first mode.

12. The method of claim 10, wherein determining whether a voltage drop across the electronic switch is lower than the first threshold value comprises:
detecting that the voltage drop across the electronic switch reaches the first threshold value

13. The method of claim 12, further comprising:
generating a diagnosis signal that signals an error in response to the voltage drop across the electronic switch not reaching the first threshold value within a predetermined time from a transition into the first mode.

14. The method of claim 12, further comprising:
generating a diagnosis signal that indicates a load current passing through the electronic switch as soon as the voltage drop across the electronic switch reaches the first threshold value.

15. The method of claim 10, further comprising:
transitioning into a second mode of operation if a specific maximum time in the first mode has passed.

16. The method of claim 10, further comprising:
detecting an overtemperature state and switching off the electronic switch as long as the overtemperature state persists.

17. The method of claim 16, wherein detecting the overtemperature state includes:
detecting that a temperature value exceeds a first temperature threshold and
detecting that the temperature value falls below a second temperature threshold which indicates an end of the overtemperature state.
